(19) United States
(12) Patent Application Publication
(10) Pub. No.: US 2014/0217366 A1
(43) Pub. Date: Aug. 7, 2014

(54) REFLECTION ORGANIC LIGHT-EMITTING DIODE DISPLAY DEVICE AND DRIVING METHOD THEREOF

(71) Applicant: YUAN ZE UNIVERSITY, Zhongli City (TW)

(72) Inventors: Tien Lung CHIU, Zhongli City (TW); Yi Peng HSIAO, Zhongli City (TW)

(73) Assignee: YUAN ZE UNIVERSITY, Zhongli City (TW)

(21) Appl. No.: 13/760,053

(22) Filed: Feb. 6, 2013

(51) Int. Cl. H01L 51/52

(52) U.S. Cl. CPC H01L 51/5271
USPC 257/40; 257/98; 438/29

(57) ABSTRACT

A reflection organic light-emitting diode (OLED) display device and driving method thereof are provided. A default cavity produces reflection light of a default wavelength through optical interference with incident light. When imposed by a voltage, an organic emitting layer produces self-luminous light for mixing, so as to change the wavelength of the reflection light and to increase brightness thereof. The mechanism helps improve energy efficiency of the OLED.

### BACKGROUND

1. Technical Field

The invention relates to an organic light-emitting diode (OLED) display device and the driving method thereof. In particular, the invention relates to an OLED display device that reflects ambient light for display in bright without bias, and uses self-luminous light for display in dark when a voltage is imposed. The driving method thereof is also disclosed.

2. Related Art

In recent years, with the vigorous development of energy-saving technology and environmental consciousness, organic light-emitting diode (OLED) has received a lot attentions in both academic and industrial communities because of its self-luminousness, wide viewing angle, fast response time, high brightness, low operating voltage, thin thickness, flexibility, simple manufacturing process, and many other advantages.

Generally speaking, to avoid reflection of ambient light that leads to a reduction in reading comfort, conventional OLED display devices usually increase the driving current or voltage to increase the brightness of the OLED, balancing the ambient light. However, increasing the driving current or voltage is very energy-consuming. It is unable to fully exhibit the energy efficiency of the OLED. Instead, this method lowers the energy efficiency thereof

In view of this, some vendors propose to add an absorbing layer to eliminate reflection light, thereby increasing the contrast of the OLED. However, this approach does not take full advantage of the ambient light. The device has to continuously consume energy to produce self-luminous light as a display light source. Thus, the above-mentioned method still cannot effectively solve the problem of poor energy efficiency of the OLED. On the other hand, some other vendors propose to use a micro-electromechanical system (MEMS) as the controller of the display device to make use of the reflection light. This creates resonance cavities at different depths inside the display device. When ambient light arrives at the display device, the depth of each resonance cavity determines the response to light of a specific wavelength (and color). Each cavity represents a sub-pixel (one of the three primary colors). Cavities of three different depths form one pixel in a reflection-type color display device to render the three primary colors. This method can take full advantage of the reflection light to improve energy efficiency. However, this method needs a static electricity to continuously drive the MEMS. In comparison with the usual OLED, the manufacturing process is more complicated.

In summary, the prior art has long had the problem of unsatisfactory energy efficiency for the OLED. It is imperative to provide an improved technical means to solve this problem.

### SUMMARY

In view of the foregoing, the invention discloses a reflection-type OLED display device and the driving method thereof

The disclosed reflection-type OLED display device comprises: a substrate, a first electrode layer, a hole transport layer, an light-emitting layer, and a second electrode layer. The substrate allows the transmission of incident light and reflection light. The first electrode layer is formed on the substrate. The hole transport layer is formed on the first electrode layer. The light-emitting layer is formed on the hole transport layer. The second electrode layer is formed on the light-emitting layer. The first and second electrode layers are used to load the driving voltage. The light-emitting layer and the hole transport layer play as a dielectric layer sandwiched between first and second electrode layers to form the resonance cavity, which produces reflection light of a default wavelength through optical interference and absorption with the incident light. When imposed by a voltage, the light-emitting layer recombines holes and electrons to produce self-luminous light, which is then used to change the default wavelength of the reflection light.

The disclosed driving method of the reflection-type OLED display device comprises the steps of: providing a substrate for the transmission of incident light and reflection light; forming a first electrode layer on the substrate to produce holes when imposed by a voltage; forming a hole transport layer for the transporting of the holes; forming an light-emitting layer on the hole transport layer to emit the photon; forming a second electrode layer on the light-emitting layer to produce electrons when imposed by a voltage; forming a resonance cavity with the light-emitting layer and the hole transport layer between first and second electrode layers; wherein the resonance cavity produces reflection light of a default wavelength through optical interference and absorption with the incident light, the light emitting layer recombines the holes and electrons to produce self-luminous light when a voltage is applied, and the self-luminous light changes the default wavelength of the reflection light.

The element and its driving method of the present invention are disclosed in the above, with the prior art the difference between the in that the present invention is to produce a default wavelength of the reflection light of the incident light through the pre-set cavity optical interference, and in the voltage applied, so that the light emitting layer to produce a self-luminous light mixing in order to change the reflection light wavelength and increase the brightness.

The present invention can be achieved through the above-mentioned technical means, to enhance the energy efficiency of the organic light-emitting diode technology efficiency.

### BRIEF DESCRIPTION OF THE DRAWINGS

The invention will become more fully understood from the detailed description given herein below illustration only, and thus is not limitative of the present invention, and wherein:

FIG. 1 is a schematic cross-sectional view of the disclosed reflection-type OLED display device;

FIG. 2 is a flow chart of the disclosed driving method for the reflection-type OLED display device;

FIG. 3 is a schematic cross-sectional view of the reflection-type OLED display device with a buffer layer;

FIG. 4 is a schematic cross-sectional view of the disclosed second electrode layer in the first embodiment; and

FIG. 5 is a schematic cross-sectional view of the disclosed second electrode layer in the second embodiment.

### DETAILED DESCRIPTION

The present invention will be apparent from the following detailed description, which proceeds with reference to the accompanying drawings, wherein the same references relate to the same elements.

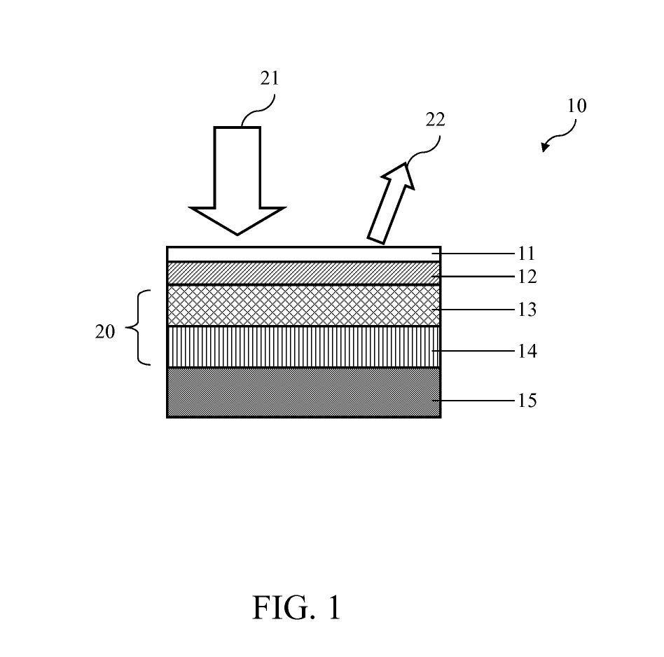

Please refer to FIG. 1 for the disclosed reflection-type OLED display device. FIG. 1 is a schematic cross-sectional view of the reflection-type OLED device. The device 10 includes: a substrate 11, a first electrode layer 12, a hole transport layer 13, an light-emitting layer 14, and a second electrode layer 15. The substrate 11 allows the transmission of incident light 21 (from external ambient light) and the reflection light 22 (generated by the light-emitting layer 14). In practice, the substrate 11 is a flexible substrate, selected from group of polyester films, plastic, or thin glasses. It should be mentioned that the substrate 11 is not limited to the above-mentioned materials. Any substance that can be used as the substrate is within the scope of the invention.

The first electrode layer 12 is formed on the substrate 11 to produce holes when imposed by a voltage. Its formation can be done by physical vapor deposition (PVD), vacuum vapor deposition, spin coating, etc. that coats indium tin oxide (ITO) onto the substrate 11. In practice, the first electrode layer 12 may be a transparent conductive film as an anode.

The hole transport layer 13 is formed on the first electrode layer 12. When the first electrode layer 12 produces holes, the hole transport layer 13 transfer the holes from the first electrode layer 12 to the light-emitting layer 14. In practice, the hole transport layer 13 can be made of triarylamine derivatives, such as NPB, TPD, PVK, etc. Such materials have a higher hole mobility under an electric field, thereby significantly improving the luminous efficiency. In addition, the junction between the hole transport layer 13 and the first electrode layer 12 can also be coated with a layer of copper phthalocyanine (CuPc) material to increase the efficiency of injecting the holes from the first electrode layer 12 to the transport layer 13. This improves the potential energy barrier between the ITO and hole transport layer 13.

The light-emitting layer 14 is formed on the hole transport layer 13, thereby forming a resonance cavity 20. When no voltage is imposed on the first electrode layer 12 and the second electrode layer 15, the resonance cavity 15 performs optical interference on the incident light 21, including constructive interference and destructive interference, in order to generate reflection light 22 of a default wavelength. The default wavelength is in the range of visible light (such as the color of red, orange, yellow, green, blue, etc.). Take the blue color as an example. The default wavelength is 400 nm to 480 nm. The method for the resonance cavity 20 to generate light of the default wavelength can be achieved by adjusting the thicknesses of the light-emitting layer 14 and the hole transport layer 13. For example, the thickness of the hole transport layer 13 is set to 60 nm, and the thickness of the light-emitting layer 14 is set to 60 nm. Simultaneously along with the thickness of other layers, e.g., the thickness of the second electrode layer 15 being set to 100 nm, the resonance cavity 20 performs optical interference on the incident light 21 so that the reflection light 22 renders the color of the reflection-type OLED display device 10 close to white. Besides, when the light-emitting layer 14 is imposed by a voltage, the holes generated by the first electrode layer 12 and the electrons generated by the second electrode layer 15 are recombined to release energy and generate self-luminous light. Light mixing changes the default wavelength of the reflection light 22. Therefore, the reflection-type OLED display device 10 can render the appropriate color according to the different wavelengths of the reflection light 22. It should be noted that the generated self-luminous light and the incident light 21 mix in the resonance cavity 20 to change the default wavelength of the reflection light 22. Therefore, different voltages can be applied to generate the self-luminous light of different wavelengths to mix with the incident light 21. As a result, the reflection-type OLED display device 10 can present different colors. That is, the invention is applicable to two cases: with and without imposing a voltage. When the intensity of the ambient light is sufficient, the resonance cavity 20 performs destructive or constructive interference so that the incident light 21 is reflected with a specific wavelength, showing the corresponding color. Therefore, no voltage is required in this case. The user can recognize the color presented by the reflection-type OLED display device 10. When the ambient light is insufficient, a voltage can be applied to the light-emitting layer 14 to generate self-luminous light as a display light source. In this case, the user can also recognize the color presented by the reflection OLED display device 10.

The second electrode layer 15 is formed on the light-emitting layer 14 to generate electrons when imposed by a voltage. The material of the second electrode layer 15 can be aluminum. In practice, the second electrode layer 15 can include a metal layer and a doping layer for forming a sub-resonance cavity. For example, a doping layer is formed on a layer of aluminum (Al) of the thickness 100 nm. The doping layer is made of Alq₃:Ag with a thickness of 20 nm to 100 nm, where the ratio between Alq₃ and Ag is 10:1. Afterwards, a layer of 7.5 nm silver (Ag) is formed on the doping layer. Alternatively, a layer of 1.2 nm LiF is formed at the junction between the metal layer and the doping layer. The second electrode layer 15 is to be described in detailed with reference to accompanying plots layer. It should be explained that both the sub-resonance cavity and the resonance cavity 20 perform optical interference. The difference between the two is that the sub-resonance cavity has more effect on the color presented by the reflection-type OLED display device 10 than the resonance cavity. In addition, although the above example describes the structure of the sub-resonance cavity, the invention does not make any restriction on this. Any structure that can perform optical interference on light should be included within the scope of the invention.

It should be noted that in practice, the disclosed reflection-type OLED display device 10 may further include a buffer layer. The buffer layer is formed at the junction between the light-emitting layer 14 and the second electrode layer 15 to form a resonance cavity with the light-emitting layer 14 and hole transport layer 13. The buffer layer will be described in detail later. In practice, the buffer layer may be made of lithium fluoride (LiF) to improve electron injection.

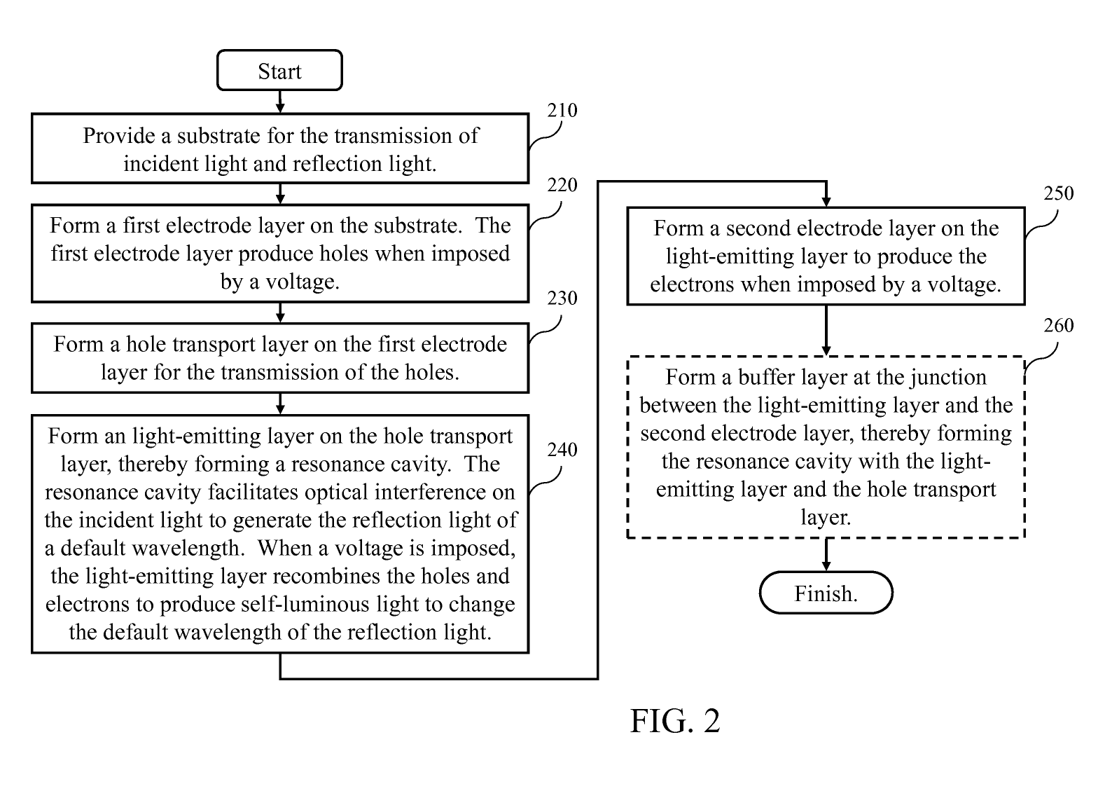

FIG. 2 shows a flowchart of the disclosed driving method for the reflection-type OLED display device. The method comprises the steps of providing a substrate for the transmission of incident light and reflection light (step 210); forming a first electrode layer on the substrate to generate holes when imposed by a voltage (step 220); forming a hole transport layer on the first electrode layer for transmitting the holes (step 230); forming the light-emitting layer on the hole transport layer, thereby forming a resonance cavity between the light-emitting layer and the hole transport layer, the resonance cavity producing reflection light of a default wavelength via optical interference with incident light and combining the holes and the electrons to produce self-luminous light when voltage is applied with the self-luminous light changing the wavelength of the reflection light (step 240); forming a second electrode layer on the light-emitting layer to generate the electrons when imposed by a voltage (step 250). Through the above-mentioned steps, the preset resonance cavity performs optical interference on the incident light to generate the reflected light of a default wavelength. When a voltage is applied, the light-emitting layer produces self-luminous light for light mixing, thereby changing the wavelength of the reflection light and increasing the brightness thereof.

In practice, a buffer layer can be first formed on the light-emitting layer. The second electrode layer is then formed on the buffer layer. The buffer layer along with the light-emitting layer and the hole transport layer form a resonance cavity (step 260). It should be noted that any material that can increase the efficiency of electron injection can be used to form the buffer layer of the invention.

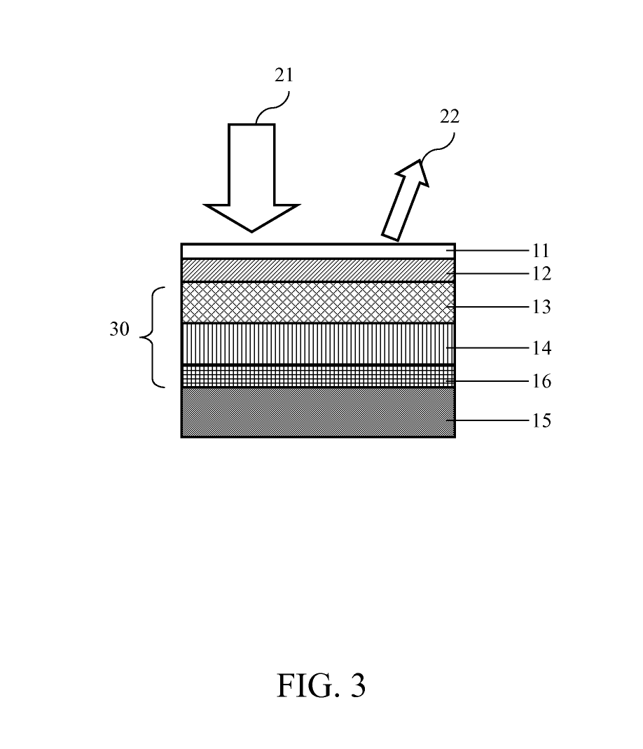

FIG. 3 is a schematic cross-sectional view of the device according to the disclosed reflection-type OLED display device with the buffer layer. In practice, to improve the efficiency of electron injection between the metal material and the organic material, the buffer layer 16 can be formed at the junction between the light-emitting layer 14 and the second electrode layer 15. Along with an light-emitting layer 14 and the hole transport layer 13, the buffer layer forms a resonance cavity 30.

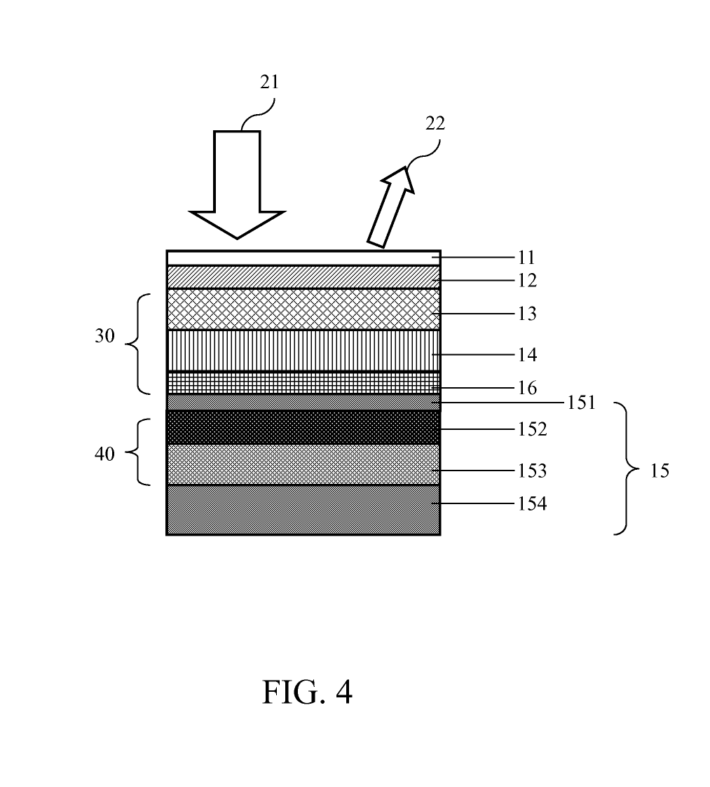

FIG. 4 is a schematic cross-sectional view of the second electrode layer according to the first embodiment of the invention. As mentioned earlier, the second electrode layer 15 includes a metal layer and a doping layer. In practice, the second electrode layer 15 may be formed in sequence with an aluminum metal layer 151, a silver metal layer 152, an Alq₃:Ag doping layer 153, and an aluminum metal layer 154, thereby forming a sub-resonance cavity 40 for optical interference.

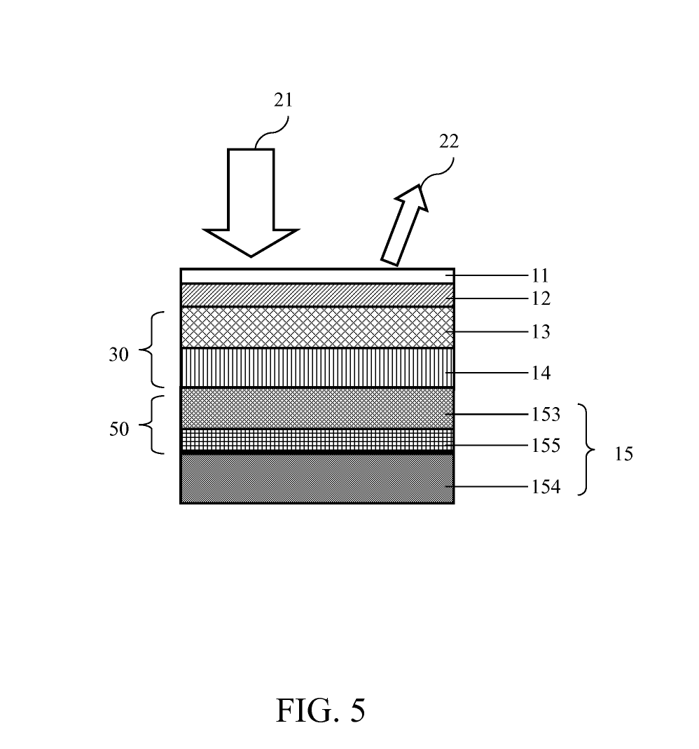

FIG. 5 is a schematic cross-sectional view of the second electrode layer according to a second embodiment of the invention. In the practice, the second electrode layer 15 has a 20 nm˜100 nm Alq₃:Ag layer as the doping layer 153, and a 100 nm aluminum layer as the metal layer 154. To increase the electron injection, a layer of LiF of thickness 1.2 nm can be formed at the junction of the doping layer 153 and the metal layer 154 as the buffer layer 155. Likewise, the doping layer 153 and the buffer layer 155 can also form a sub-resonance cavity 50 for optical interference.

In summary, it is observed that the invention and the prior art differ in that a default resonance cavity facilitates optical interference with incident light to produce the reflection light of a default wavelength. When a voltage is applied, the light-emitting layer produces self-luminous light for mixing, thereby changing the wavelength of the reflection light and increasing the brightness thereof. Through these means, the invention solves the problems existing in the prior art and achieves the goal of increasing the energy efficiency of to the OLED.

Although the invention has been described with reference to specific embodiments, this description is not meant to be construed in a limiting sense. Various modifications of the disclosed embodiments, as well as alternative embodiments, will be apparent to persons skilled in the art. It is, therefore, contemplated that the appended claims will cover all modifications that fall within the true scope of the invention.

1. A reflection-type organic light-emitting diode (OLED) display device, comprising:
a substrate for the transmission of incident light and reflection light;
a first electrode layer formed on the substrate to generate holes when a voltage is imposed;
a hole transport layer formed on the first electrode layer for transmitting the holes;
an light-emitting layer formed on the hole transport layer to form a resonance cavity in between, wherein the resonance cavity generates the reflection light of a default wavelength by optical interference on the incident light, when imposed by a voltage, the light-emitting layer recombines the holes and the electrons to generate self-luminous light, and the self-luminous light changes the default wavelength of the reflection light; and
a second electrode layer formed on the light-emitting layer to generate the electrons when a voltage is imposed.

2. The reflection-type OLED display device of claim 1 further comprising a buffer layer formed at the junction between the light-emitting layer and the second electrode layer to form the resonance cavity with the light-emitting layer and the hole transport layer, the buffer layer being made of lithium fluoride.

3. The reflection-type OLED display device of claim 2, wherein the thicknesses of the light-emitting layer, the hole transport layer, and the buffer layer are adjusted to change the default wavelength, the default wavelength being in the range of visible light.

4. The reflection-type OLED display device of claim 1, wherein the light-emitting layer adjusts the wavelengths of the self-luminous light and the reflection layer according to the magnitude of the imposed voltage.

5. The reflection-type OLED display device of claim 1, wherein the second electrode layer include at least one metal layer and one doping layer to form a sub-resonance cavity for optical interference, the metal layer is made of copper or silver, and the doping layer is made of a silver-doped Alq₃ material.

6. A driving method for a reflection-type OLED display device, comprising the steps of:
providing a substrate for the transmission of incident light and reflection light;
forming a first electrode layer on the substrate, the first electrode layer generating holes when imposed by a voltage;
forming a hole transport layer on the first electrode layer to transmit the holes;
forming an light-emitting layer on the hole transport layer, thereby forming a resonance cavity between the light-emitting layer and the hole transport layer; wherein the resonance cavity produces the reflection light of a default wavelength by optical interference with the incident light, when imposed by a voltage, the light-emitting layer recombines the holes and the electrons to generate self-luminous light, and the self-luminous light changes the default wavelength of the reflection light; and
forming a second electrode layer on the light-emitting layer to generate the electrons when imposed by a voltage.

7. The driving method of claim 6 further comprising the step of forming a buffer layer at the junction between the light-emitting layer and the second electrode layer and forming the resonance cavity with the light-emitting layer and the hole transport layer.

8. The driving method of claim 7, wherein the thicknesses of the light-emitting layer, the hole transport layer, and the buffer layer are adjusted to change the default wavelength, the default wavelength being in the range of visible light.

9. The driving method of claim 6, wherein the light-emitting layer adjusts the wavelengths of the self-luminous light and the reflection layer according to the magnitude of the imposed voltage.

10. The driving method of claim 6, wherein the second electrode layer include at least one metal layer and one doping layer to form a sub-resonance cavity for optical interference, the metal layer is made of copper or silver, and the doping layer is made of a silver-doped Alq₃ material.
